(19) United States
(12) Patent Application Publication
(10) Pub. No.: US 2009/0052128 A1
(43) Pub. Date: Feb. 26, 2009

(54) MOUNTING FRAME STRUCTURE FOR FLAT PANEL DISPLAY DEVICE

(76) Inventors: SONG SAN YEH, Taipei (TW); Yi Chung Su, Taipei (TW)

Correspondence Address: G. LINK CO., LTD., 3550 BELL ROAD, MINOOKA, IL, 60447, US

(21) Appl. No.: 11/956,743

(22) Filed: Dec. 14, 2007

(30) Foreign Application Priority Data
Aug. 23, 2007 (CN) 200710146127.4

(51) Int. Cl. H05K 5/02

(52) U.S. Cl. 361/681

(57) ABSTRACT

The present invention relates to a mounting frame structure for flat panel display device that allows the user to conveniently mount or dismount a flat panel display device on or from a wall and adjust the tilt of the flat panel display device with ease to a degree comfortable for viewing by the user.

### FIELD OF THE INVENTION

The present invention relates to a mounting frame structure for flat panel display device, more particularly a mounting frame structure that allows the user to conveniently mount or dismount a flat panel display device on or from a wall and adjust the tilt of the flat panel display device with ease to a degree comfortable for viewing by the user.

### BACKGROUND OF THE INVENTION

The dawning of digital age, prevalence of the Internet, and changes of digital broadcast signals have fueled the significant evolvement of display technology. Flat panel display (FPD) monitors offer the advantages of lightweight, thin form, power saving and free of radiation. It is expected to become the mainstream choice for computer monitor and home television.

Generally a stand is needed for the placement of FPD monitor on a desk for support and fixation or the adjustment of monitor angle.

In recent years, FPD monitor stand and FPD are commonly separately fabricated and then assembled. When a stand-included FPD monitor is placed on a desk, it is also easy to adjust the tilting angles of the FPD.

Conventional wall mount for FPD comprises a wall bracket that can be mounted on the wall. On the wall bracket there is securely disposed a base stand with a ␣-shaped bottom positioning stand thereon. A π-shaped bottom lateral adjustment stand is disposed at one of the a connecting bracket made of board material and folded in long columnar shape such that the bottom lateral adjustment stand is fastened to the bottom positioning stand and secured with a bolt. As such, the connecting bracket can swing laterally to a certain degree on the bottom positioning stand. At the other end of the connecting bracket there is disposed a ␣-shaped top positioning stand bolted with a top lateral adjustment stand in such a manner that the top lateral adjustment stand can swing laterally to a certain degree thereon. At the other end of the top lateral adjustment stand there is disposed a longitudinal slot bolted with a T-shaped vertical adjustment stand in such a manner that the vertical adjustment stand is able to swing vertically to a certain degree at the other end of the top lateral adjustment stand. In addition, on top of the vertical adjustment stand there are in sequence provided with a connecting plate and an angle adjusting stand to secure the flat panel display.

The conventional mounting frame structure for flat panel display allows flat panel display thereon to have front and back distance, left and right angle and viewing angle adjusted. But the actual operation is cumbersome. The present invention aims to provide a mounting structure that is easy for the user to make adjustment.

### SUMMARY OF THE INVENTION

The object of invention is to provide a mounting frame structure for flat panel display device that allows the user to conveniently mount or dismount a flat panel display device on or from a wall and adjust the tilt of the flat panel display device with ease to a degree comfortable for viewing by the user.

The objects, features and effects of the invention are described in detail below with embodiments in reference to the accompanying drawings.

### DESCRIPTION OF THE DRAWINGS

FIG. 1 is an exploded view of the first embodiment of the invention;

FIG. 2 is a perspective assembly view of the first embodiment of the invention;

FIG. 3 is a first-state side view of the first embodiment of the invention;

FIG. 4 is a second-state side view of the first embodiment of the invention;

FIG. 5 is a third-state side view of the first embodiment of the invention;

FIG. 6 is a partial exploded view of the second embodiment of the invention;

FIG. 7 is a first-state side view of the embodiment in FIG. 6 in assembly;

FIG. 8 is a second-state side view of the embodiment in FIG. 6 in assembly;

FIG. 9 is a third-state side view of the embodiment in FIG. 6 in assembly;

FIG. 10 is another partial exploded view of the second embodiment of the invention;

FIG. 11 is a first-state side view of the embodiment in FIG. 10 in assembly;

FIG. 12 is a second-state side view of the embodiment in FIG. 10 in assembly;

FIG. 13 is a third-state side view of the embodiment in FIG. 10 in assembly;

FIG. 14 is a partial exploded view of the third embodiment of the invention;

FIG. 15 is a perspective assembly view of the embodiment in FIG. 6;

FIG. 16 is a first-state side view of the embodiment in FIG. 14 in assembly;

FIG. 17 is a second-state side view of the embodiment in FIG. 14 in assembly; and

FIG. 18 is a third-state side view of the embodiment in FIG. 14 in assembly.

### DETAILED DESCRIPTION OF THE INVENTION

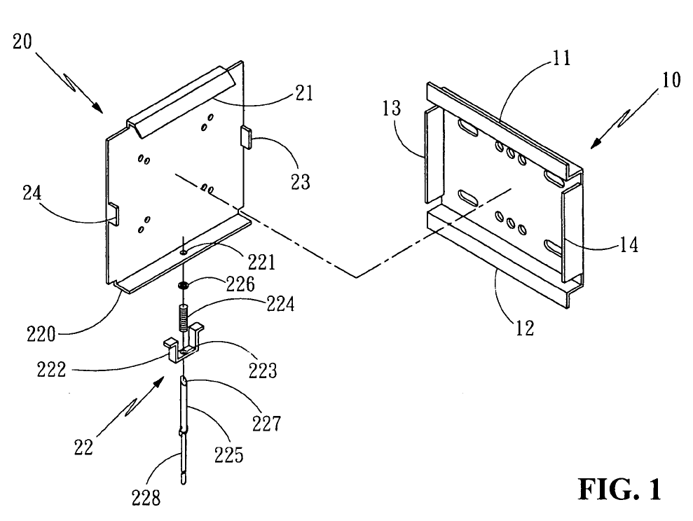

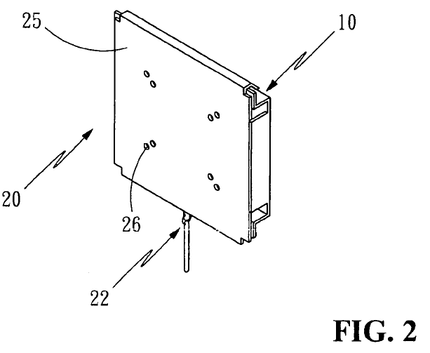

Referring to FIG. 1 and FIG. 2, FIG. 1 is an exploded view of the first embodiment of the invention, and FIG. 2 is a perspective assembly view of the first embodiment of the invention. As shown, the present invention relates to a mounting frame structure for flat panel display device, comprising a base plate (10) and a first connecting plate (20). The embodiments of the invention arc described in detail below.

The base plate (10) is primarily a flat plate fastened to a wall. The top and bottom sides of the base plate (10) are extendedly disposed with a first engaging plate (11) and a second engaging plate (12), and the left and right sides of the base plate (10) are extendedly disposed with a first side plate (13) and a second side plate (14).

The first connecting plate (20) is primarily a flat plate that allows the secure mounting of a flat panel display device (not shown in the figures) thereon and can be assembled to the base plate (10). The first connecting plate (20) is disposed with a first fastening piece (21) at the top side that can engage the first engaging plate (11). The first connecting plate (20) is disposed with a first quick release apparatus (22) at the bottom side which can engage the second engaging plate (12). The first quick release apparatus (22) consists of a first flat plate (220) disposed on the first connecting plate (20) and configured with a first through hole (221); a first π-shaped piece (222) fastened to the first flat plate (220) and having thereon a second through hole (223) being co-axial with the first through hole (221); a first elastic element (224) such as a spring disposed between the first π-shaped piece (222) and the first flat plate (220) to provide elastic restoring force; a first latching piece (225) disposed through the first through hole (221) and the second through hole (223) and having the elastic element (224) coil around it; and a first stopper piece (226) disposed between the elastic element (224) and the first flat plate (220) and snapped to the first latching piece (225). The part of the first latching piece (225) moving in the first through hole (221) has a first beveled guide plane (227), and the end of the first latching piece (225) is arranged with a first rope (228) to facilitate operation and control. The left and right sides of the first connecting plate (20) are arranged with a first stopper plate (23) and a second stopper plate (24) which confine the lateral movement of the first connecting plate (20) when they are respectively in contact with the first side plate (13) and the second side plate (14).

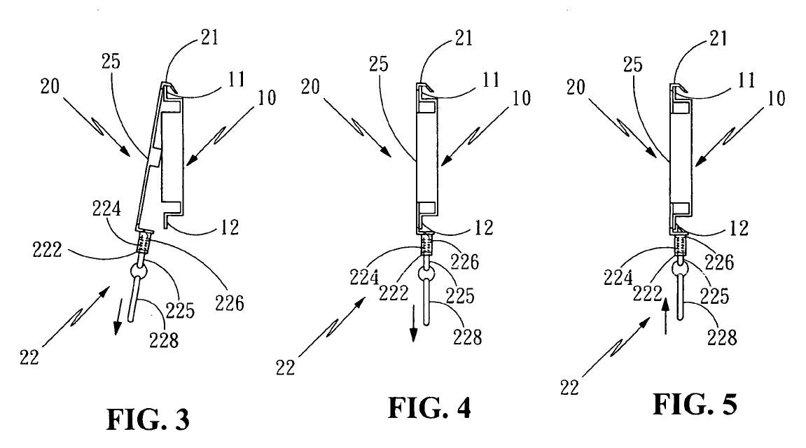

Referring to FIGS. 3-5, FIG. 3 is a first-state side view of the first embodiment of the invention in a first state; FIG. 4 is a second-state side view of the first embodiment of the invention; and FIG. 5 is a third-state side view of the first embodiment of the invention. As shown, to assemble the first connecting plate (20) on the base plate (10), first of all fasten the first fastening piece (21) to the first engaging plate (11) and let the first stopper plate (23) and the second stopper plate (24) contact the inside (or outside) of the first side plate (13) and the second side plate (14) to confine the lateral movement of the first connecting plate (20). Next pull the first rope (228) to feed the first latching piece (225) into the first through hole (221) or use the first beveled guide plane (227) such that when the first beveled guide plane (227) is in contact with the base plate (10), the first latching piece (225) would be fed into the first through hole (221) under external force. When the second engaging plate (12) passes through the first latching piece (225), the first latching piece (225) would protrude from the first through hole (221) under the elastic restoring force of the first elastic element (224) to form a state of lock-in.

The outer surface of the first connecting plate (20) is defined as the mounting surface (25) for the mounting of a flat panel display (not shown in the figures). Through the mounting surface (25) of the first connecting plate (20) and the base plate (10) fastened on a wall to or from which the first connecting plate (20) can be assembled or disassembled, the flat panel display may be conveniently mounted or dismounted on or from the wall through the assembly or disassembly of the first connecting plate (20) to or from the base plate (10). In addition, the mounting surface (25) of the first connecting plate (20) is configured with a plurality of mounting holes (26), which form a specific distribution pattern in coordination with the flat panel display and respectively penetrate the first connecting plate (20) such that the first connecting plate (20) can be fastened in advance through those mounting holes (26) and bolts (not shown in the figures).

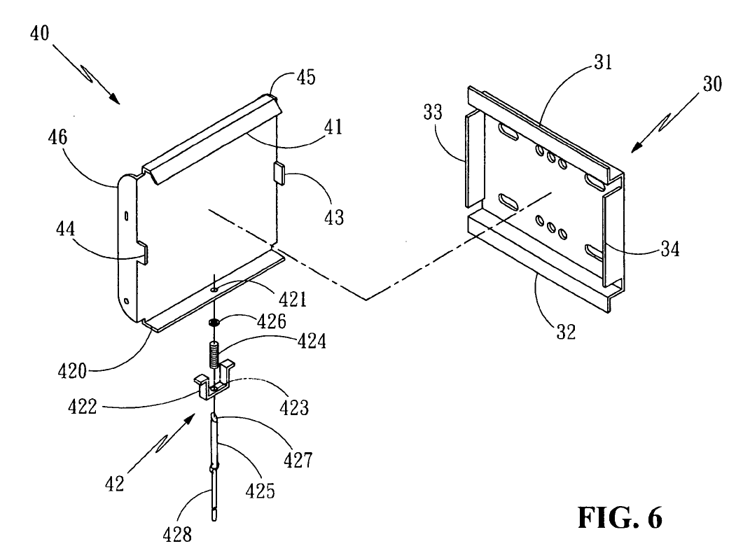

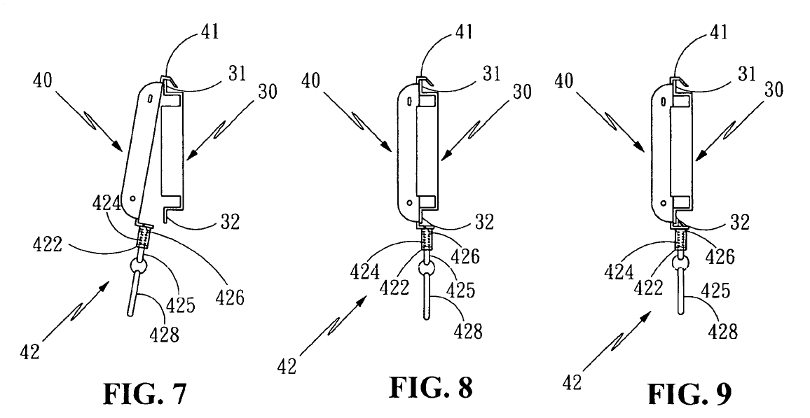

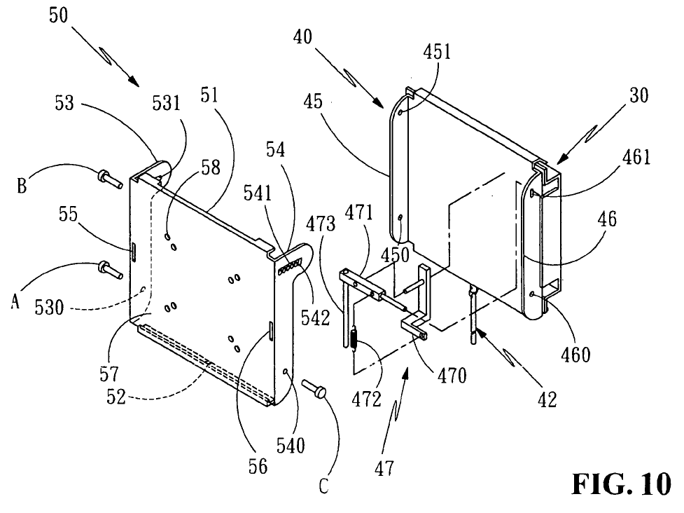

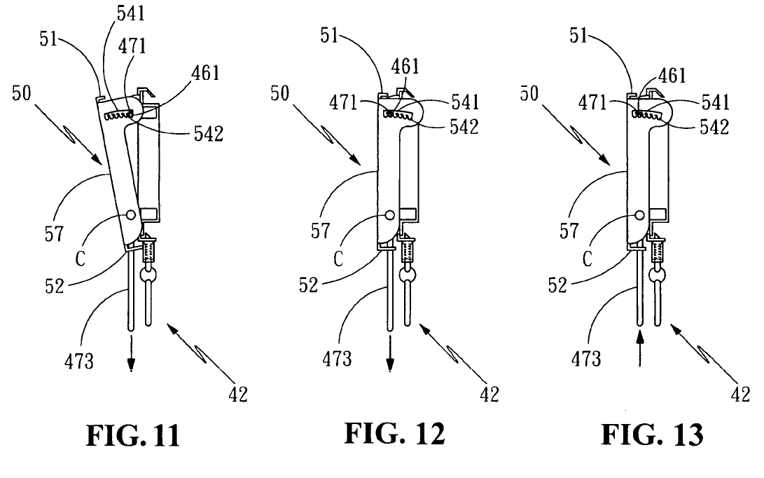

Referring to FIGS. 6-13. FIG. 6 is a partial exploded view of the second embodiment of the invention; FIG. 7 is a first-state side view of the embodiment in FIG. 6 in assembly; FIG. 8 is a second-state side view of the embodiment in FIG. 6 in assembly; FIG. 9 is a third-state side view of the embodiment in FIG. 6 in assembly; FIG. 10 is another partial exploded view of the second embodiment of the invention; FIG. 11 is a first-state side view of the embodiment in FIG. 10 in assembly; FIG. 12 is a second-state side view of the embodiment in FIG. 10 in assembly; and FIG. 13 is a third-state side view of the embodiment in FIG. 10 in assembly. As shown, the present invention provides a mounting frame structure for flat panel display device, comprising a base plate (30), a first connecting plate (40), arid a movable plate (50). This embodiment is described in detail below.

The base plate (30) is primarily a flat plate fastened to a wall. The top and bottom sides of the base plate (30) are extendedly disposed with a first engaging plate (31) and a second engaging plate (32), and the left and right sides of the base plate (30) are extendedly disposed with a first side plate (33) and a second side plate (34).

The first connecting plate (40) is primarily a flat plate that can be assembled to the base plate (30). The first connecting plate (40) is disposed with a first fastening piece (41) at the top side that can engage the first engaging plate (31). The first connecting plate (40) is disposed with a first quick release apparatus (42) at the bottom side which can engage the second engaging plate (32). The first quick release apparatus (42) consists of a first flat plate (420) disposed on the first connecting plate (40) and configured with a first through hole (421); a first π-shaped piece (422) fastened to the first flat plate (420) and having thereon a second through hole (423) being co-axial with the first through hole (421); a first elastic element (424) such as a spring disposed between the first π-shaped piece (422) and the first flat plate (420) to provide elastic restoring force; a first latching piece (425) disposed through the first through hole (421) and the second through hole (423) and having the elastic element (424) coil around it; and a first stopper piece (426) disposed between the elastic element (424) and the first flat plate (420) and snapped to the first latching piece (425). The part of the first latching piece (425) moving in the first through hole (421) has a first beveled guide plane (427), and the end of the first latching piece (425) is arranged with a first rope (428) to facilitate operation and control. The left and right sides of the first connecting plate (40) are arranged with a first stopper plate (43) and a second stopper plate (44) which confine the lateral movement of the first connecting plate (40) when they are respectively in contact with the first side plate (33) and the second side plate (34).

The movable plate (50) is primarily a flat plate disposed between the base plate (30) and the first connecting plate (40). The movable plate (50) is provided with a first trough piece (51) at the top side, a second trough piece (52) at the bottom side, and a third side plate (53) and a fourth side plate (54) on the left and right side respectively. The third side plate (53) is disposed a fifth through hole (530) and a first slide slot (531). The fourth side plate (54) is disposed with a sixth through hole (540) and a second slide slot (541). The second slide slot (541) is further configured with a plurality of positioning grooves (542). The first connecting plate (40) is extendedly disposed with a fifth side plate (45) and a sixth side plate (46) on its left and right side. The fifth side plate (45) is provided with a seventh through hole (450) and an eighth through hole (451). The seventh through hole (450) and the fifth through hole (530) form a hinge joint with the insertion of a first bolt (A). The eighth through hole (451) and the first slide slot (531) form a hinge joint with the insertion of a second bolt (B) in such a way that the second bolt (B) can slide in the first slide slot (531). The sixth side plate (46) is provided with a ninth through hole (460) and a first through groove (461). The ninth through hole (460) and the sixth through hole (540) form a hinge joint with the insertion of a third bolt (C). The first connecting plate (40) is disposed with a lock-in set (47). The lock-in set (47) consists of a stationary element (470) arranged on the first connecting plate (40), a locking element (471) pin-jointed to the stationary element (470) and having one end penetrating through the second slide slot (541) and the first through groove (461), and a second elastic element (472) such as a spring. One end of the second elastic element (472) is securely attached to the stationary element (470) and the other end is securely attached to the locking element (471) and situated between the joint at where the locking element (471) is attached to the stationary element (470) and the first through groove (461). The other end of the locking element (471) is disposed with a second rope (473) to facilitate the control of its movement. Moreover, the movable plate (50) is further provided with a first engaging slot (55) and a second engaging slot (56) on its left and right side.

The outer surface of the movable plate (50) is defined as the mounting surface (57) for the mounting of a flat panel display (not shown in the figures). Through the mounting surface (57) of the movable plate (50), the base plate (30) fastened on a wall to or from which the first connecting plate (40) can be assembled or disassembled, and the angle adjustment of the movable plate (50), the flat panel display may be conveniently mounted or dismounted on or from the wall through the assembly or disassembly of the first connecting plate (40) and have its angle adjusted. In addition, the mounting surface (57) of the movable plate (50) is configured with a plurality of mounting holes (58), which form a specific distribution pattern in coordination with the flat panel display and respectively penetrate the movable plate (50) such that the movable plate (50) can be fastened in advance through those mounting holes (58) and bolts (not shown in the figures).

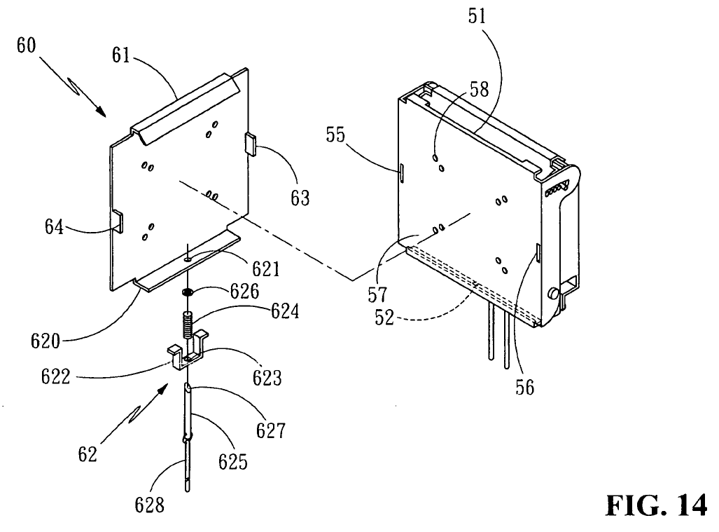

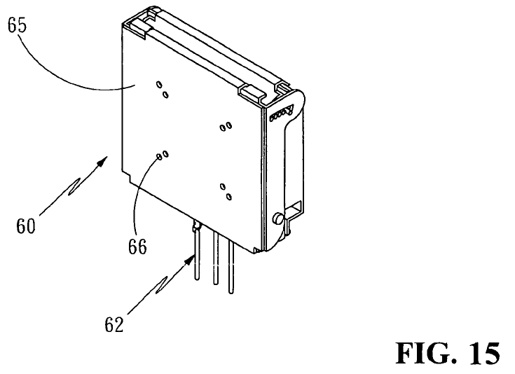

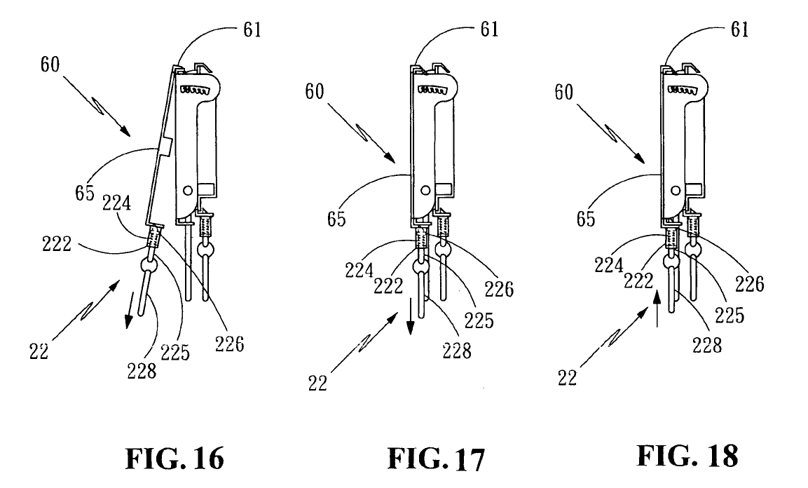

Referring to FIGS. 14-18, FIG. 14 is a partial exploded view of the third embodiment of the invention; FIG. 15 is a perspective assembly view of the embodiment in FIG. 6; FIG. 16 is a first-state side view of the embodiment in FIG. 14 in assembly; FIG. 17 is a second-state side view of the embodiment in FIG. 14 in assembly; and FIG. 18 is a third-state side view of the embodiment in FIG. 14 in assembly. As shown. the third embodiment of the invention is added with a second connecting plate (60) based on the structure in the second embodiment. The second connecting plate (60) is a flat plate that allows the secure mounting of a flat panel display device (not shown in the figures) thereon. The second connecting plate (60) is disposed with a second fastening piece (61) at the top side that can engage the first trough piece (51), and a second quick release apparatus (62) at the bottom side. The second quick release apparatus (62) consists of a second flat plate (620) disposed on the second connecting plate (60) and configured with a third through hole (621); a second π-shaped piece (622) attached to the second flat plate (620) and having thereon a fourth through hole (623) being co-axial with the third through hole (621); a third elastic element (624) disposed between the second π-shaped piece (622) and the second flat plate (620) to provide elastic restoring force: a second latching piece (625) disposed through the third through hole (621) and the fourth through hole (623) and having the third elastic element (624) coil around it; and a second stopper piece (626) disposed between the third elastic element (624) and the second flat plate (620) and snapped to the second latching piece (625). The part of the second latching piece (625) moving in the third through hole (621) has a second beveled guide plane (627), and the end of the second latching piece (625) is arranged with a third rope (628) to facilitate operation and control. The left and right sides of the second connecting plate (60) are arranged with a third stopper plate (63) and a fourth stopper plate (64), which can be inserted respectively into the first engaging slot (55) and the second engaging slot (56).

The first connecting plate (40) and the movable plate (50) are assembled to each other through the first bolt (A), the second bolt (B), the third bolt (C), and the lock-in set (47), and when the locking element (471) engages the positioning grooves (542), the movable plate (50) is kept from tilting and moving. When tilting the movable plate (50) is desired, pull the second rope (473) to disengage the locking element (471) from the positioning grooves (542) based on the lever principle. At this time, the movable plate (50) can be tilted along the axis of the first bolt (A) and the third bolt (C). When the second rope (473) is released, the locking element (471) would again engage the positioning grooves (542) under the restoring force provided by the second elastic element (472).

To assemble the first connecting plate (40) on the base plate (30), first fasten the first fastening piece (41) to the first engaging plate (31) and let the first stopper plate (43) and the second stopper plate (44) contact the inside (or outside) of the first side plate (33) and the second side plate (34) to confine the lateral movement of the first connecting plate (40). Next pull the first rope (428) to feed the first latching piece (425) into the first through hole (421) or use the first beveled guide plane (427) such that when the first beveled guide plane (427) is in contact with the base plate (30), the first latching piece (425) would be fed into the first through hole (421) under external force. When the second engaging plate (32) passes through the first latching piece (425), the first latching piece (425) would protrude from the first through hole (421) under the elastic restoring force of the first elastic element (424) to form a state of lock-in.

To connect the second connecting plate (60) to the movable plate (50), first fasten the second fastening piece (61) to the first trough piece (51) and then align the third stopper plate (63) and the fourth stopper plate (64) with the first engaging slot (55) and the second engaging slot (56) respectively. Next pull the third rope (628) to feed the second latching piece (625) into the third through hole (621) or use the second beveled guide plane (627) such that when the second beveled guide plane (627) is in contact with the second connecting plate (60), the second latching piece (625) would be fed into the third through hole (621) under external force. When the second trough piece (52) passes through the second latching piece (625), the second latching piece (625) would protrude from the third through hole (621) under the elastic restoring force of the third elastic element (624) to form a state of lock-in. When the assembly is completed, the third stopper plate (63) and the fourth stopper plate (64) can be inserted respectively into the first engaging slot (55) and the second engaging slot (56).

Based on the second embodiment described, the third embodiment of the invention allows the mounting of a flat panel display (not shown in the figure) through the second connecting plate (60), and the outer surface of the second connecting plate (60) is defined as the mounting surface (65) for the mounting of a flat panel display (not shown in the figures). Through the assembly or disassembly of the second connecting plate (60) on the movable plate (50) which is fastened on a wall, the flat panel display can be conveniently mounted or dismounted to or from the wall through the assembly or disassembly of the first connecting plate (40) without disassembling the assembled structure of the first connecting plate (40) and the movable plate (50). The mounting frame structure for flat panel display device according to the invention can then be a modularized structure with or without the function of angle adjustment as desired. In addition, the mounting surface (65) of the second connecting plate (60) can be configured with a plurality of mounting holes (66), which form a specific distribution pattern in coordination with the flat panel display and respectively penetrate the second connecting plate (60) such that the second connecting plate (60) can be fastened in advance through those mounting holes (58) and bolts (not shown in the figures).

As such, the mounting frame structure for flat panel display device provided by the invention allows the user to conveniently mount or dismount a flat panel display device on or from a wall and adjust the tilt of the flat panel display device with ease to achieve comfortable viewing. Thus the invention possesses inventiveness and meets the essential criteria for a patent.

The preferred embodiments of the present invention have been disclosed in the examples. However the examples should not be construed as a limitation on the actual applicable scope of the invention, and as such, all modifications and alterations without departing from the spirits of the invention and appended claims shall remain within the protected scope and claims of the invention.

What is claimed is:

1. A mounting frame structure for flat panel display device, comprising:
a base plate being primarily a flat plate, the top and bottom sides of the base plate being extendedly disposed with a first engaging plate and a second engaging plate; and
a first connecting plate being primarily a flat plate, the first connecting plate being disposed with a first fastening piece at the top side that can engage the first engaging plate and being disposed with a first quick release apparatus at the bottom side that can engage the second engaging plate, the first quick release apparatus consisting of a first flat plate disposed on the first connecting plate and configured with a first through hole; a first π-shaped piece fastened to the first flat plate and having thereon a second through hole being co-axial with the first through hole; a first elastic element disposed between the first π-shaped piece and the first flat plate to provide elastic restoring force; a first latching piece disposed through the first through hole and the second through hole and having the elastic element coil around it; and a first stopper piece disposed between the elastic element and the first flat plate and snapped to the first latching piece.

2. The mounting frame structure according to claim 1, wherein and the left and right sides of the base plate are extendedly disposed with a first side plate and a second side plate, and the left and right sides of the first connecting plate are disposed with a first stopper plate and a second stopper plate, the contact of the first stopper plate and the second stopper plate with the first side plate and the second side plate being able to confine the lateral movement of the first connecting plate.

3. The mounting frame structure according to claim 2, wherein the first connecting plate and a movable plate could be assembled together.

4. The mounting frame structure according to claim 3, wherein the movable plate is a flat plate disposed between the base plate and the first connecting plate, the movable plate being provided with a first trough piece at the top side, a second trough piece at the bottom side, and a third side plate and a fourth side plate on the left and right side respectively, the third side plate being disposed a fifth through hole and a first slide slot, the fourth side plate being disposed with a sixth through hole and a second slide slot, the second slide slot being further configured with a plurality of positioning grooves.

5. The mounting frame structure according to claim 4, wherein the first connecting plate is extendedly disposed with a fifth side plate and a sixth side plate on its left and right side, the fifth side plate being provided with a seventh through hole and an eighth through hole, the seventh through hole and the fifth through hole forming a hinge joint with the insertion of a first bolt, the eighth through hole and the first slide slot forming a hinge joint with the insertion of a second bolt in such a way that the second bolt can slide in the first slide slot, the sixth side plate being provided with a ninth through hole and a first through groove, the ninth through hole and the sixth through hole forming a hinge joint with the insertion of a third bolt, the first connecting plate being disposed with a lock-in set, the lock-in set comprising a stationary element arranged on the first connecting plate; a locking element pin-jointed to the stationary element and having one end penetrating through the second slide slot and the first through groove; and a second elastic element, one end of the second elastic element being securely attached to the stationary element and the other end being securely attached to the locking element and situated between the joint at where the locking element is attached to the stationary element and the first through groove.

6. The mounting frame structure according to claim 5, wherein the movable plate is further assembled to the second connecting plate.

7. The mounting frame structure according to claim 6, wherein the second connecting plate is primarily a flat plate and disposed with a second fastening piece at the top side that can engage the first engaging plate, and a second quick release apparatus at the bottom side, the second quick release apparatus consisting of a second flat plate disposed on the second connecting plate and configured with a third through hole; a second π-shaped piece disposed on the second flat plate and having thereon a fourth through hole being co-axial with the third through hole; a third elastic element disposed between the second π-shaped piece and the second flat plate to provide elastic restoring force; a second latching piece disposed through the third through hole and the fourth through hole and having the third elastic element coil around it; and a second stopper piece disposed between the third elastic element and the second flat plate and snapped to the second latching piece, the part of the second latching piece protruding from the third through hole being able to engage the second trough piece.

8. The mounting frame structure according to claim 7, wherein the left and right sides of the second connecting plate are arranged with a third stopper plate and a fourth stopper plate, and the left and right sides of the movable plate are arranged with a first engaging slot and a second engaging slot which allow the insertion of the third stopper plate and the fourth stopper plate respectively.

9. The mounting frame structure according to claim 7, wherein the part of the first latching piece moving in the first through hole has a first beveled guide plane, and the part of the second latching piece moving in the third through hole has a second beveled guide plane.

10. The mounting frame structure according to claim 7, wherein the first elastic element, the second elastic element, and the third elastic element are a spring.
